(19) United States
(12) Patent Application Publication
(10) Pub. No.: US 2004/0004508 A1
(43) Pub. Date: Jan. 8, 2004

(54) Apparatus for automatically selecting the internal or external resistor

(76) Inventors: Kuo-Chang Wang, Hsinchu (TW); Ching-Hung Tseng, Hsinchu (TW)

Correspondence Address: KUO-CHANG WANG, P.O. BOX 7-820, TAIPEI, TW

(21) Appl. No.: 10/189,851

(22) Filed: Jul. 8, 2002

(51) Int. Cl. H03L 5/00

(52) U.S. Cl. 327/308

(57) ABSTRACT

The present invention relates to an apparatus for automatically selecting an internal or external resistor, characterized by that a built-in control unit is placed in the front of the oscillator of the integrated circuit, and such control unit comprises a detection circuit for coupling the external resistor and oscillator, and an internal resistor bridging the detection circuit in parallel with its output end such that the detection circuit can automatically detect whether or not there is any input of serial signal from the external resistor to switch into the external or internal resistor at appropriate time, and further select inputting the optimal operating frequency of the control IC.

### BACKGROUND OF THE INVENTION

1. Field of the Invention

The present invention relates to an apparatus for automatically selecting internal or external resistor, characterized by that a built-in control unit is placed in front of the oscillator of the integrated circuit, and such control unit comprises a detection circuit for coupling the external resistor and oscillator, and an internal resistor bridging the detection circuit in parallel with its output end, such that the detection circuit can automatically detect whether or not there is any input of serial signal from the external resistor to switch into the external or internal resistor at appropriate time, and further select inputting the optimal operating frequency of the control IC.

2. Description of the Prior Art

In general, the consumption IC chips are widely used in all types of products. To cater for different use of program and devices such as hardware, manufacturers usually uses a single pin of the IC to externally connect the resistor on hardware peripherals, and adjust or set the IC operating frequency to drive the device. Therefore, it is essential to operate the related operation frequency of the externally connected resistor. To adopt the diversified frequencies required by different manufacturers, the prior art makes use of the other pin of the integrated circuit to cross connect with another set of resistor, so as to process the distinction, selection and switch to the appropriate frequency. Such additional pin will finally increase the bearing cost of the related components and thus become a waste as economical trouble.

### SUMMARY OF THE INVENTION

The primary objective of the present invention is to provide an apparatus for automatically selecting the internal or external resistor, more particularly to a control unit having a detection circuit and an internal resistor, being set in front of the oscillator of an IC, such that the circuit can automatically detect and switch to the external or internal resistor at an appropriate time, and further select the optimal operating frequency for the control IC.

The secondary objective of the present invention is to provide an apparatus for automatically selecting the internal or external resistor, and allows the IC to independently control the operation by designing a built-in internal resistor within the control unit.

A further objective of the present invention is to provide an apparatus for automatically selecting the internal or external resistor, in which a single pin of the IC is used to set the control unit, which greatly reduces the manufacturing cost of the double pin design, and prevents the manufacturing process from being moved to outside.

### BRIEF DESCRIPTION OF THE DRAWINGS

FIG. 1 is a circuit block diagram of a preferred embodiment of the present invention;

FIG. 2 is a flow chart of the self-detection of the control unit according to the present invention.

### DELTAILED DESCRIPTION OF THE PREFERRED EMBODIMENT

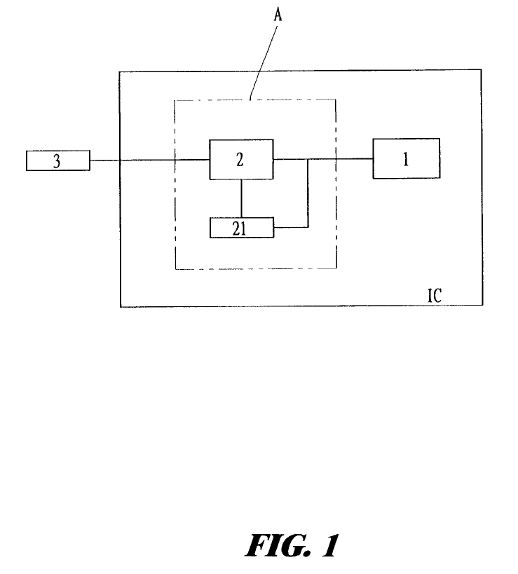

Referring to FIG. 1, an apparatus for automatically selecting the internal or external resistor comprises a control unit A disposed in the front of an oscillator 1 of an IC unit, such control unit includes a detection circuit 2 and an internal resistor 21 in which the front input end of the detection circuit 2 is for the input of an external resistor 3, and a first output end at the rear is coupled to the oscillator 1; and an end of the internal resistor 21 is connected to the second output end of the detection circuit in series and the other end connected to the first output end of the detection circuit in parallel. Such arrangement constitutes the main characteristic of the control device of the present invention.

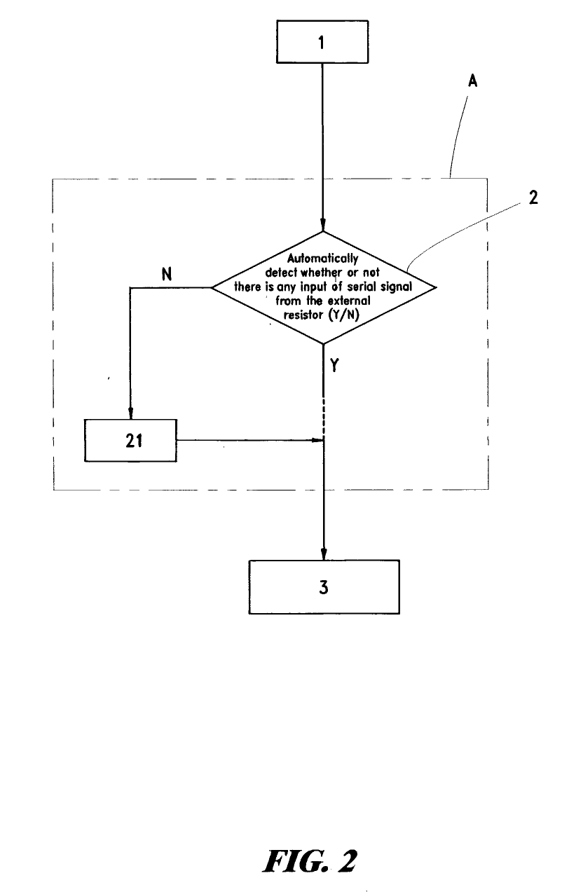

Referring to FIG. 2, the present invention uses particularly a self-detecting design of a detection circuit 2 to turn off the internal resistor 21 when there is an input signal from a resistor 3 externally connected to the front, and then directly conducts the external resistor via the first output end of the external resistor to drive the oscillator; when there is no input signal from external resistor, the second output end will enable the internal resistor 21 to conduct the connection to the oscillator to timely switch the internal or external resistor according to the detected result, and further to select the optimal operating frequency for the control IC. Such arrangement constitutes a practical and simple control.

While the invention has been described by means of specific embodiments, numerous modifications and variations could be made thereto by those skilled in the art without departing from the scope and spirit of the invention set forth in the claims.

What is claimed is:

1. An apparatus for automatically selecting internal or external resistor is characterized by: In front of the oscillator of the integrated circuit there is a control unit which includes a detection circuit and an internal resistor; wherein:
the detection circuit, the input end of the front for the input from an external resistor, and the first output end at the rear connect to the oscillator;
the internal resistor has one end connected to the second output end of the detection circuit, and the other end is connected in parallel with the first output end of the detection circuit;
the self-detecting design of the detection circuit in the control unit allows the automatic detection and switch to the internal or external resistor and further selection of the input for the optimal operating frequency of the integrated circuit providing an easy control and practical utility.
